(19) United States
(12) Patent Application Publication
(10) Pub. No.: US 2025/0138081 A1
(43) Pub. Date: May 1, 2025

(54) METHOD AND APPARATUS FOR MEASURING LINEARITY OF TESTED CIRCUIT

(71) Applicant: Realtek Semiconductor Corp., HsinChu (TW)

(72) Inventors: Chih-Chieh Wang, HsinChu (TW); Yu-Jhang Lin, HsinChu (TW)

(73) Assignee: Realtek Semiconductor Corp., HsinChu (TW)

(21) Appl. No.: 18/926,307

(22) Filed: Oct. 25, 2024

(30) Foreign Application Priority Data
Oct. 26, 2023 (TW) 112140963

(51) Int. Cl. G01R 31/28

(52) U.S. Cl. CPC G01R 31/2832

(57) ABSTRACT

A method and an apparatus for measuring linearity of a tested circuit are provided. The method includes: utilizing a signal generator to output a first tone signal and a second tone signal, wherein the tested circuit generates an intermodulation signal according to the first tone signal and the second tone signal; utilizing a signal analyzing device to detect an intermodulation power of the intermodulation signal; utilizing the signal generator to further output a cancel tone signal and control a cancel power of the cancel tone signal according to the intermodulation power; and utilizing the signal analyzing device to detect a total power of the intermodulation signal and the cancel tone signal, and controlling a phase of the cancel tone signal according to the total power, in order to minimize the total power in response to the phase of the cancel tone signal being modified to a target phase.

### BACKGROUND OF THE INVENTION

### 1. Field of the Invention

The present invention is related to measurement of circuit linearity, and more particularly, to a method and an apparatus for measuring linearity of a tested circuit.

### 2. Description of the Prior Art

In a wireless communication system, when a power amplifier (PA) operating in a nonlinear region is interfered with by two or more signals, these signals may undergo intermodulation in the PA and intermodulation distortion signals may be generated. Thus, some problems such as degradation of signal receiving ability, signal distortion and reduction of signal selectivity are introduced, which may affect receiving performance of nearby signals. In addition, components of a memory effect generated by the PA operating in the nonlinear region are complicated, and a corresponding model is hard to build. Thus, it is typical to utilize measurement results to represent features of the PA.

Measurement methods of related arts typically need a lot of instruments, however, which makes an overall cost extremely high. Thus, there is a need for a novel method and associated apparatus, which can obtain linearity information of a tested device (e.g. the PA mentioned above) without introducing any side effect or in a way that is less likely to introduce side effects.

### SUMMARY OF THE INVENTION

An objective of the present invention is to provide a method and an apparatus for measuring linearity of a tested circuit, which can reduce a number of instruments being utilized in an overall measurement system.

At least one embodiment of the present invention provides a method for measuring linearity of a tested circuit. The method comprises: utilizing a signal generator to output a first tone test signal and a second tone test signal to the tested circuit, wherein the tested circuit generates an intermodulation signal according to the first tone test signal and the second tone test signal; utilizing a signal analyzing device to receive the intermodulation signal and detect an intermodulation power of the intermodulation signal; utilizing the signal generator to further output a cancel tone signal and control a cancel power of the cancel tone signal according to the intermodulation power; and utilizing the signal analyzer to detect a total power of the intermodulation signal and the cancel tone signal, and controlling a phase of the cancel tone signal according to the total power, in order to minimize the total power in response to the phase of the cancel tone signal being modified to a target phase.

At least one embodiment of the present invention provides an apparatus for measuring linearity of a tested circuit. The apparatus comprises a signal generator, a signal analyzing device and a host device, wherein the host device is coupled to the signal generator and the signal analyzing device. The signal generator is configured to output a first tone test signal and a second tone test signal to the tested circuit, wherein the tested circuit generates an intermodulation signal according to the first tone test signal and the second tone test signal. The signal analyzing device is configured to receive the intermodulation signal and detect an intermodulation power of the intermodulation signal. When the signal generator further outputs a cancel tone signal, the host device is configured to control a cancel power of the cancel tone signal according to the intermodulation power. In addition, the signal analyzer detects a total power of the intermodulation signal and the cancel tone signal, and the host device controls a phase of the cancel tone signal according to the total power, in order to minimize the total power in response to the phase of the cancel tone signal being modified to a target phase.

The method and the apparatus provided by the embodiments of the present invention can utilize a signal generator operating in a multi-tone mode to output multi-tone signals, which enables the first tone test signal, the second tone test signal and the cancel tone signal mentioned above to be output from a single signal generator, instead of being respectively output from multiple single-tone signal generators. In addition to obtaining power information of the intermodulation signal, the present invention iteratively modifies the phase of the cancel tone signal in a corresponding range, in order to find a target phase of the intermodulation signal according to total powers which are detected based on these phases. Thus, the present invention can measure power information and phase information of the intermodulation signal under a condition of utilizing only one signal generator.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating an apparatus for measuring linearity of a tested circuit according to an embodiment of the present invention.

FIG. 2 is a diagram illustrating a working flow of a method for measuring linearity of a tested circuit according to an embodiment of the present invention.

FIG. 3 is a diagram illustrating an example of the method shown in FIG. 2 according to an embodiment of the present invention.

FIG. 4 is a diagram illustrating a working flow of obtaining phase information of an intermodulation signal according to an embodiment of the present invention.

### DETAILED DESCRIPTION

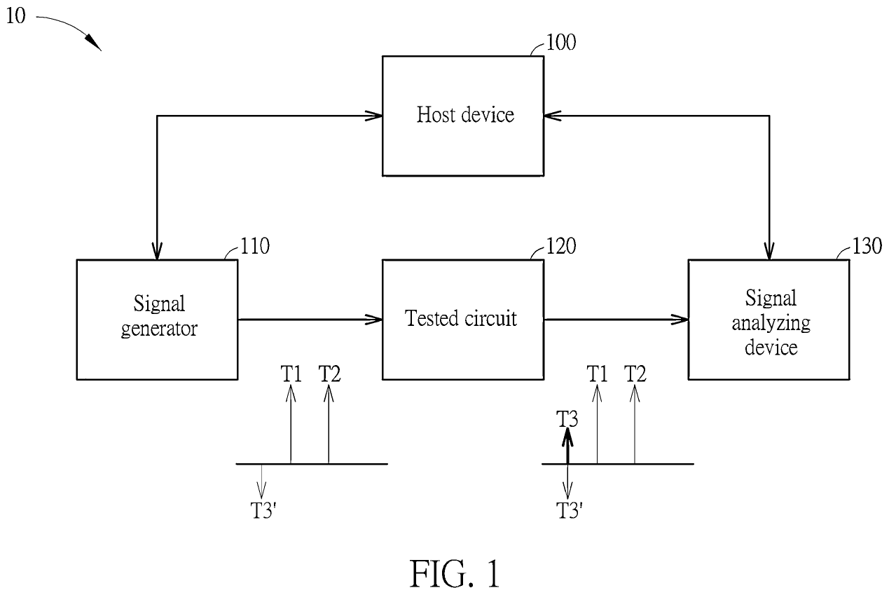

FIG. 1 is a diagram illustrating an apparatus such as a measurement system 10 for measuring linearity of a tested circuit 120 such as a device under test (DUT) circuit according to an embodiment of the present invention, where the tested circuit 120 may be a power amplifier (PA) utilized in a wireless communication system. As shown in FIG. 1, the measurement system 10 may comprise a signal generator 110, a tested circuit 120, a signal analyzing device 130 and a host device 100, where the tested circuit 120 is coupled to an output terminal of the signal generator 110 in order to receive signals from the signal generator 110, and is coupled to an input terminal of the signal analyzing device 130 to transmit processed signals to the signal analyzing device 130. In addition, the host device 100 is coupled to the signal generator 110 and the signal analyzing device 130, and may control operations of the signal generator 110 and the signal analyzing device 130 based on a program code (e.g. a program code running on the host device 100). In addition, the signal generator 110 may be a multi-tone signal generator which is able to operate in a multi-tone mode, and the signal analyzing device 130 may be a spectrum analyzer.

In this embodiment, the signal generator 110 may be set to operate in a multi-tone mode in order to concurrently output a first tone test signal T1 and a second tone test signal T2 to the tested circuit 120 (e.g. the signal generator 110 may output a multi-tone test signal which comprises the first tone test signal T1 and the second tone test signal T2), where the signal generator 110 does not output any cancel tone signal at the beginning, and the tested circuit 120 may transmit the first tone tested signal T1 after being amplified and the second tone test signal T2 after being amplified to the signal analyzing device 130. It should be noted that any signal received by the tested circuit 120 (e.g. a signal shown in a left side of the tested circuit 120 in FIG. 1) and a result of amplifying this signal by the tested circuit 120 (e.g. a corresponding signal shown in a right side of the tested circuit 120 in FIG. 1) are illustrated by a same symbol for better comprehension. As, however, an amplifying operation of the tested circuit is not completely linear, the tested circuit 120 may generate an intermodulation signal T3 according to the first tone test signal T1 and the second tone test signal T2 from the signal generator 110 (e.g. performing intermodulation on the first tone test signal T1 and the second tone test signal T2 to generate the intermodulation signal T3). For example, when frequencies of the first tone test signal T1 and the second tone test signal T2 are f1 and f2, respectively, the tested circuit 120 may generate third-order intermodulation (IMD3) signals having frequencies equal to (2×f1−f2) and (2×f2−f1) as the tested circuit 120 operates in a nonlinear region, where the IMD3 signals having the frequencies equal to (2×f1−f2) and (2×f2−f1) may be examples of the intermodulation signal T3. As the signal generator 110 does not output any cancel tone signal at this moment, the signal analyzing device 130 may receive the intermodulation signal T3 from the tested circuit 120, and detect an intermodulation power of the intermodulation signal T3 by detecting a power of the signal having the frequency equal to (2×f1−f2) or (2×f2−f1).

The host device 100 may obtain the intermodulation power from the signal analyzing device 130, and then control the signal generator 110 to further output a cancel tone signal T3′, where a cancel frequency of the cancel tone signal T3′ is equal to (or quite close to) an intermodulation frequency (e.g. (2×f1−f2) or (2×f2−f1)) of the intermodulation signal T3. For example, the host device 100 may control the signal generator 110 to output a multi-tone test signal, and this multi-tone test signal may comprise the first tone test signal T1, the second tone test signal T2 and the cancel tone signal T3′. More particularly, the host device may control a cancel power of the cancel tone signal T3′ according to the intermodulation power. Thus, the tested circuit 120 may receive the cancel tone signal T3′ from the signal generator 110, and transmit the cancel tone signal T3′ after being amplified to the signal analyzing device 130. Under this condition, the signal analyzing device 130 may detect a total power of the intermodulation signal T3 and the cancel tone signal T3′ output from the tested circuit 120 (e.g. detecting the power of the signal having the frequency equal to (2×f1−f2) or (2×f2−f1)), and the host device 100 may transmit a corresponding instruction to the signal generator 110 according to the total power detected by the signal analyzing device 130, in order to control a phase of the cancel tone signal T3′, to minimize the total power in response to the phase of the cancel tone signal T3′ being modified to a target phase. As the intermodulation signal T3 and the cancel tone signal T3′ output from the tested circuit 120 have an optimized cancellation result (i.e. the detected total power is minimized) when the phase of the cancel tone signal T3′ is modified to the target phase, the host device 100 may calculate and derive a phase of the intermodulation signal T3 according to the target phase.

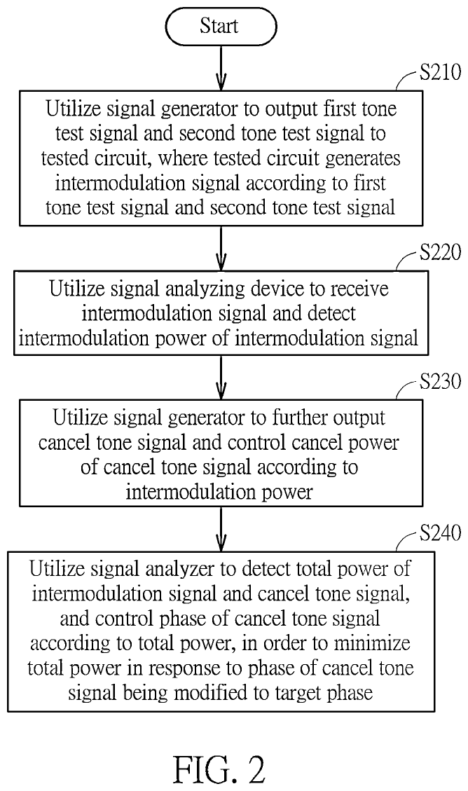

FIG. 2 is a diagram illustrating a working flow of a method for measuring linearity of the tested circuit 120 according to an embodiment of the present invention, where the method shown in FIG. 2 may be executed by the measurement system 10 shown in FIG. 1. It should be noted that the working flow shown in FIG. 2 is for illustrative purposes only, and is not meant to be a limitation of the present invention. For example, one or more steps may be added, deleted or modified in the working flow shown in FIG. 2. In addition, if a same result can be obtained, these steps do not have to be executed in the exact order shown in FIG. 2.

In Step S210, the measurement system 10 may utilize the signal generator 110 to output the first tone test signal T1 and the second tone test signal T2 to the tested circuit 120, where the tested circuit 120 generates the intermodulation signal T3 according to the first tone test signal T1 and the second tone test signal T2.

In Step S220, the measurement system 10 may utilize the signal analyzing device 130 to receive the intermodulation signal T3 and detect the intermodulation power of the intermodulation signal T3.

In Step S230, the measurement system 10 may utilize the signal generator 110 to further output the cancel tone signal T3′ and control the cancel power of the cancel tone signal T3′ according to the intermodulation power.

In Step S240, the measurement system 10 may utilize the signal analyzer 130 to detect the total power of the intermodulation signal T3 and the cancel tone signal T3′, and control the phase of the cancel tone signal T3′ according to the total power, in order to minimize the total power in response to the phase of the cancel tone signal T3′ being modified to the target phase.

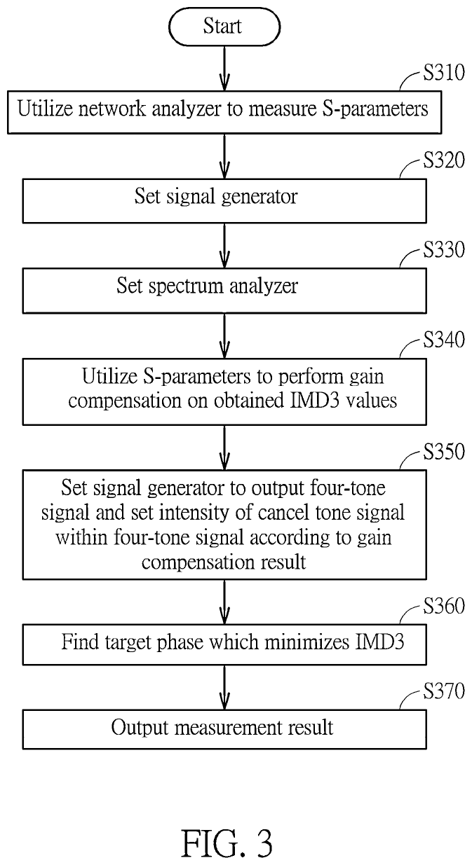

FIG. 3 is a diagram illustrating an example of the method shown in FIG. 2 according to an embodiment of the present invention. It should be noted that the working flow shown in FIG. 3 is for illustrative purposes only, and is not meant to be a limitation of the present invention. For example, one or more steps may be added, deleted or modified in the working flow shown in FIG. 3. In addition, if a same result can be obtained, these steps do not have to be executed in the exact order shown in FIG. 3.

In Step S310, the measurement system 10 may utilize a network analyzer to measure scattering parameters (S-parameters) of the tested circuit 120, where the S-parameters measured by the network analyzer may comprise gain information and phase information of the tested circuit 120, which can be used for compensating/calibrating a frequency response of the tested circuit 120.

In Step S320, the measurement system 10 may set the signal generator 110, and more particularly, may enable a multi-tone function of the signal generator 110 and set spacing between multi-tone test signals (e.g. a frequency difference between the first tone test signal T1 and the second tone test signal T2), in order to output the multi-tone test signals with this spacing.

In Step S330, the measurement system 10 may set the signal analyzing device 130 such as a spectrum analyzer. For example, the signal analyzer typically has a built-in auto-setting function, and more particularly, can automatically adjust parameters such as resolution bandwidth, video bandwidth, a number of averaging times, and a reference level to suitable values. In addition, a frequency span of the spectrum analyzer is preferably set to a dimension of 1 Megahertz (MHz), to make measured signal powers (e.g. a signal power of a frequency equal to f1, a signal power of a frequency equal to f2, a signal power of a frequency equal to (2×f1−f2), and a signal power of a frequency equal to (2×f2−f1)) have better precision. In particular, the measurement system 10 (e.g. the signal analyzing device 130 or the host device 100) may obtain IMD3 values by the following calculation:

$$IMD 3 L = P ( 2 \times f 1 - f 2 ) - P ( f 1 ) \qquad ( 1 )$$

$$IMD 3 R = P ( 2 \times f 2 - f 1 ) - P ( f 2 ) \qquad ( 2 )$$

IMD3L may represent impact of an intermodulation signal occurring in a left side (e.g. a left side in a frequency domain) of the multi-tone test signals caused by intermodulation, where P (2×f1−f2) may be the signal power of the frequency equal to (2×f1−f2) expressed in decibels (dB), and P (f1) may be the signal power of the frequency equal to f1 expressed in dB. IMD3R may represent impact of an intermodulation signal occurring in a right side (e.g. a right side in the frequency domain) of the multi-tone test signals caused by intermodulation, where P (2×f2−f1) may be the signal power of the frequency equal to (2×f2−f1) expressed in dB, and P (f2) may be the signal power of the frequency equal to f2 expressed in dB.

In Step S340, the host device 100 may utilize the S-parameters obtained in Step S310 to perform gain compensation on the IMD3 values IMD3L and IMD3R obtained in Step S330, to make the measurement result be closer to real features of the tested circuit 120 (e.g. the PA) under a wide-band condition.

In Step S350, the host device 100 may set the signal generator 110 to output a four-tone signal (e.g. signals having frequencies equal to (2×f1−f2), f1, f2 and (2×f2−f1)) and set intensity of a cancel tone signal within the four-tone signal. For example, the host device 100 may control the cancel power of the cancel tone signal T3′ (e.g. the signal having the frequency equal to (2×f1−f2) or the signal having the frequency equal to (2×f2−f1)) output from the signal generator 110 according to the intermodulation power obtained in Step 330 mentioned above (e.g. the IMD3 values IMD3L and IMD3R) and the S-parameters obtained in Step S310, to make the cancel power of the cancel tone signal T3′ output from the test signal 120 approach the intermodulation power mentioned above as much as possible. In this embodiment, the host device 100 may set the signal generator 110 to disable the signal having the frequency equal to (2×f2-f1) and set the cancel power of the signal having the frequency equal to (2×f1−f2) according to the compensation result mentioned above, in order to detect the IMD3 value IMD3L first in the following steps.

In Step S360, the host device 100 may set the signal generator 110 to modify a phase of the signal having the frequency equal to (2×f1−f2) and find a phase which minimizes the IMD3 value IMD3L detected by the signal analyzing device 130.

In Step S370, the host device 100 may record the above information and output a measurement result of the intermodulation signal (e.g. a measurement result of the signal having the frequency equal to (2×f1−f2)).

It should be noted that, after measurement related to the IMD3 value IMD3L is completed, the host device 100 may set the signal generator to disable the signal having the frequency equal to (2×f1−f2) and set the cancel power of the signal having the frequency equal to (2×f2−f1) according to the compensation result mentioned above, and Steps S360 and S370 may be executed to detect the IMD3 value IMD3R, in order to output a measurement result of the signal having the frequency equal to (2×f2−f1). In some embodiments, the host device 100 may control the signal generator 110 to change the spacing between the frequencies f1 and f2, and execute the Steps S330 to S370 again, in order to obtain a measurement result under different frequency spacing.

In addition, the host device 100 may perform compensation or calibration on the target phase found in Step S360 according to the S-parameters of the tested circuit 120, in order to obtain a phase measurement result of the intermodulation signal. In addition, the host device 100 may find the target phase according to a specific algorithm, which can reduce time for finding the target phase.

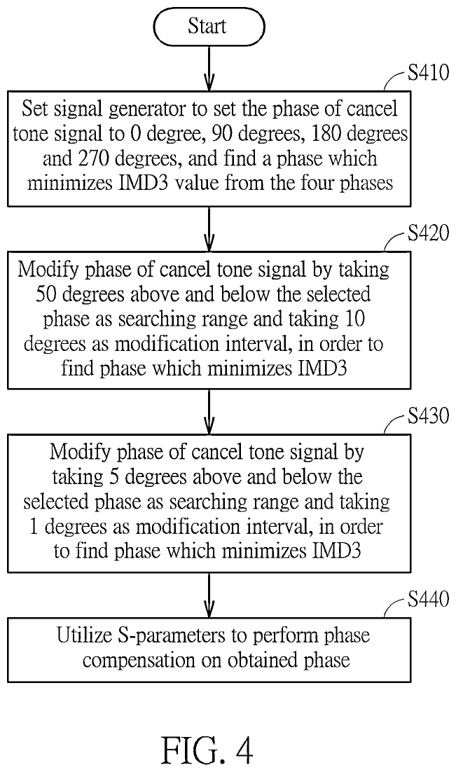

FIG. 4 is a diagram illustrating a working flow of obtaining phase information of an intermodulation signal (e.g. the signal having the frequency equal to (2×f1−f2) or the signal having the frequency equal to (2×f2−f1)) according to an embodiment of the present invention. It should be noted that the working flow shown in FIG. 4 is for illustrative purposes only, and is not meant to be a limitation of the present invention. For example, one or more steps may be added, deleted or modified in the working flow shown in FIG. 4. In addition, if a same result can be obtained, these steps do not have to be executed in the exact order shown in FIG. 4.

In Step S410, the host device 100 may set the signal generator 110 to set the phase of the cancel tone signal T3′ to multiple first candidate phase values, sequentially, where the total power is equal to multiple first power values in response to the phase of the cancel tone signal T3′ being set to the multiple first candidate phase values, respectively. The host device 100 may select a first specific phase value corresponding to a minimum first power value of the multiple first power values from the multiple first candidate phase values. For example, the phase of the cancel tone signal T3′ may be modified to 0 degree, 90 degrees, 180 degrees and 270 degrees, and the host device 100 may find a phase which minimizes the IMD3 value from the four phases. When the target phase is 71 degrees, the phase of 90 degrees among the four phases may minimize the IMD3 value, and the host device 100 may select the phase of 90 degrees.

In Step S420, the host device 100 may set the signal generator 110 to set the phase of the cancel tone signal T3′ to multiple second candidate phase values corresponding to the first specific phase value, sequentially, where the total power is equal to multiple second power values in response to the phase of the cancel tone signal T3′ being set to the multiple second candidate phase values, respectively. The host device 100 may select a second specific phase value corresponding to a minimum second power value of the multiple second power values from the multiple second candidate phase values. For example, the host device 100 may modify the phase of the cancel tone signal T3′ by taking 50 degrees above and below the phase selected in Step S410 as a searching range and taking 10 degrees as a modification interval, in order to find the phase which minimizes the IMD3 value. When the target phase is 71 degrees and the phase of 90 degrees is selected in Step S410, the phase of the cancel tone signal T3′ may be modified to 40 degrees, 50 degrees, 60 degrees, 70 degrees, 80 degrees, 90 degrees, 100 degrees, 110 degrees, 120 degrees, 130 degrees and 140 degrees, and the host device 100 may determine that the IMD3 value is minimized in response to the phase of the cancel tone signal T3′ being modified to 70 degrees.

In Step S430, the host device 100 may set the signal generator 110 to set the phase of the cancel tone signal T3′ to multiple third candidate phase values corresponding to the second specific phase value, sequentially, where the total power is equal to multiple third power values in response to the phase of the cancel tone signal T3′ being set to the multiple third candidate phase values, respectively. The host device 100 may select a third specific phase value corresponding to a minimum third power value of the multiple third power values from the multiple third candidate phase values to be the target phase. For example, the host device 100 may modify the phase of the cancel tone signal T3′ by taking 5 degrees above and below the phase selected in Step S420 as a searching range and taking 1 degree as a modification interval, in order to find the phase which minimizes the IMD3 value. When the target phase is 71 degrees and the phase of 70 degrees is selected in Step S420, the phase of the cancel tone signal T3′ may be modified to 65 degrees, 66 degrees, 67 degrees, 68 degrees, 69 degrees, 70 degrees, 71 degrees, 72 degrees, 73 degrees, 74 degrees and 75 degrees, and the host device 100 may determine that the IMD3 value is minimized in response to the phase of the cancel tone signal T3′ being modified to 71 degrees, and thereby determine the target phase is 71 degrees.

In Step S440, the host device 100 may perform compensation or calibration on the target phase according to the S-parameters of the tested circuit 120, in order to obtain a phase measurement result of the intermodulation signal. For example, the host device 100 may utilize the S-parameters of the tested circuit 120 to perform phase compensation on a phase value obtained in Step S430 (e.g. the target phase), where the phase of the cancel tone signal T3′=−(the phase of the intermodulation signal T3+S21 parameter). Thus, the phase of the intermodulation signal T3 may be obtained by calculation according to the target phase and the S21 parameter within the S-parameters.

In addition, the signal analyzing device 130 does not have to be implemented by the spectrum analyzer. In some embodiments, the signal analyzing device 130 may be a power spectrum density (PSD) calculating circuit implemented by digital circuits, to thereby prevent introducing costs of the spectrum analyzer. In particular, the PSD calculating circuit may be configured to calculate a power distribution condition of a signal at different frequencies, where the PSD calculating circuit may perform associated calculation based on the Periodogram Method or the Welch Method, but the present invention is not limited thereto. The Periodogram Method and the Welch Method are well known techniques in the field of PSD, and related details are therefore omitted here for brevity.

To summarize, the method and the apparatus provided by the embodiments of the present invention can utilize a signal generator operating in a multi-tone mode to output a multi-tone signal, to thereby reduce the number of signal generators. In addition, the present invention can gradually reduce the searching range of the target phase and increase the precision of searching the target phase, to find the target phase without fully scanning all phases. More particularly, a frequency response of the tested circuit 120 can be considered together by measuring the S-parameters thereof, and therefore the measurement result with better precision can be obtained. In view of the above, the present invention can reduce equipment cost and time cost of measuring the PA, and the precision of the measurement result can be improved without introducing any side effect or in a way that is less likely to introduce side effects.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for measuring linearity of a tested circuit, comprising:
utilizing a signal generator to output a first tone test signal and a second tone test signal to the tested circuit, wherein the tested circuit generates an intermodulation signal according to the first tone test signal and the second tone test signal;
utilizing a signal analyzing device to receive the intermodulation signal and detect an intermodulation power of the intermodulation signal;
utilizing the signal generator to further output a cancel tone signal and control a cancel power of the cancel tone signal according to the intermodulation power; and
utilizing the signal analyzing device to detect a total power of the intermodulation signal and the cancel tone signal, and controlling a phase of the cancel tone signal according to the total power, in order to minimize the total power in response to the phase of the cancel tone signal being modified to a target phase.

2. The method of claim 1, wherein an intermodulation frequency of the intermodulation signal is equal to a cancel frequency of the cancel tone signal.

3. The method of claim 1, wherein controlling the cancel power of the cancel tone signal according to the intermodulation power comprises:
controlling the cancel power of the cancel tone signal according to the intermodulation power and scattering parameters (S-parameters) of the tested circuit.

4. The method of claim 1, further comprising:
calibrating the target phase according to scattering parameters (S-parameters) of the tested circuit to obtain a phase measurement result of the intermodulation signal.

5. The method of claim 1, wherein utilizing the signal analyzing device to detect the total power of the intermodulation signal and the cancel tone signal and controlling the phase of the cancel tone signal according to the total power, in order to minimize the total power in response to the phase of the cancel tone signal being modified to the target phase comprises:
setting the phase of the cancel tone signal to multiple first candidate phase values, sequentially, wherein the total power is equal to multiple first power values in response to the phase of the cancel tone signal being set to the multiple first candidate phase values, respectively;
selecting a first specific phase value corresponding to a minimum first power value of the multiple first power values from the multiple first candidate phase values;
setting the phase of the cancel tone signal to multiple second candidate phase values corresponding to the first specific phase value, sequentially, wherein the total power is equal to multiple second power values in response to the phase of the cancel tone signal being set to the multiple second candidate phase values, respectively; and
selecting a second specific phase value corresponding to a minimum second power value of the multiple second power values from the multiple second candidate phase values.

6. An apparatus for measuring linearity of a tested circuit, comprising:
a signal generator, configured to output a first tone test signal and a second tone test signal to the tested circuit, wherein the tested circuit generates an intermodulation signal according to the first tone test signal and the second tone test signal;
a signal analyzing device, configured to receive the intermodulation signal and detect an intermodulation power of the intermodulation signal;
a host device, coupled to the signal generator and the signal analyzing device, wherein when the signal generator further outputs a cancel tone signal, the host device is configured to control a cancel power of the cancel tone signal according to the intermodulation power;
wherein the signal analyzing device detects a total power of the intermodulation signal and the cancel tone signal, and the host device controls a phase of the cancel tone signal according to the total power, in order to minimize the total power in response to the phase of the cancel tone signal being modified to a target phase.

7. The apparatus of claim 6, wherein an intermodulation frequency of the intermodulation signal is equal to a cancel frequency of the cancel tone signal.

8. The apparatus of claim 6, wherein the host device sets the signal generator according to the intermodulation power and scattering parameters (S-parameters) of the tested circuit to control the cancel power of the cancel tone signal.

9. The apparatus of claim 6, wherein the host device calibrates the target phase according to scattering parameters (S-parameters) of the tested circuit to obtain a phase measurement result of the intermodulation signal.

10. The apparatus of claim 6, wherein:
the signal generator sets the phase of the cancel tone signal to multiple first candidate phase values, sequentially, wherein the total power is equal to multiple first power values in response to the phase of the cancel tone signal being set to the multiple first candidate phase values, respectively;
the host device selects a first specific phase value corresponding to a minimum first power value of the multiple first power values from the multiple first candidate phase values;
the signal generator sets the phase of the cancel tone signal to multiple second candidate phase values corresponding to the first specific phase value, sequentially, wherein the total power is equal to multiple second power values in response to the phase of the cancel tone signal being set to the multiple second candidate phase values, respectively; and
the host device selects a second specific phase value corresponding to a minimum second power value of the multiple second power values from the multiple second candidate phase values.
